(19) United States
(12) Patent Application Publication
(10) Pub. No.: US 2026/0026035 A1
(43) Pub. Date: Jan. 22, 2026

(54) SEMICONDUCTOR DEVICE

(71) Applicant: Renesas Electronics Corporation, Tokyo (JP)

(72) Inventor: Takahiro MORI, Tokyo (JP)

(21) Appl. No.: 19/253,304

(22) Filed: Jun. 27, 2025

(30) Foreign Application Priority Data
Jul. 19, 2024 (JP) 2024-116122

(51) Int. Cl. H10D 30/65; H10D 30/01

(52) U.S. Cl. CPC H10D 30/65; H10D 30/0281

(57) ABSTRACT

A semiconductor device includes a semiconductor substrate having an upper surface, a first source layer formed in the semiconductor substrate and disposed at the upper surface, a first drain layer formed in the semiconductor substrate and disposed at the upper surface so as to be spaced apart from the first source layer in a first direction, a first drain insulating film formed at the upper surface and located between the first source layer and the first drain layer in the first direction, a first gate insulating film formed on the upper surface and located between the first drain insulating film and the first source layer in the first direction, and a first gate electrode formed on the first gate insulating film and on the first drain insulating film.

### CROSS-REFERENCE TO RELATED APPLICATIONS

The disclosure of Japanese Patent Application No. 2024-116122 filed on Jul. 19, 2024, including the specification, drawings and abstract is incorporated herein by reference in its entirety.

### BACKGROUND

This disclosure relates to a semiconductor device.

There are disclosed techniques listed below.
[Patent Document 1] Japanese Unexamined Patent Application Publication No. 2023-69620

Patent Document 1 discloses a semiconductor device. The semiconductor device disclosed in Patent Document 1 includes a semiconductor substrate, a drain insulating film, a gate insulating film, and a gate electrode.

The semiconductor substrate has an upper surface. The semiconductor substrate includes a source layer and a drain layer which are formed in the semiconductor substrate and disposed at the upper surface. The source layer and the drain layer are spaced apart from each other in a first direction. A trench is formed at the upper surface of the semiconductor substrate. The trench is located between the source layer and the drain layer in the first direction. The drain insulating film is formed in the trench. The gate insulating film is formed on the upper surface of the semiconductor substrate, located between the drain insulating film and the source layer in the first direction. The gate electrode is formed on the gate insulating film and on the drain insulating film.

The drain insulating film has a first end facing the source layer and a second end facing the drain layer in the first direction. In the drain insulating film, a plurality of first slits extending from the first end to the second end in the first direction are formed. The plurality of first slits are arranged with an interval between two first slits adjacent to each other in a second direction perpendicular to the first direction in plan view. In the gate electrode, a plurality of second slits are formed. As a result, in the semiconductor device disclosed in Patent Document 1, the area ratio of the gate electrode is reduced.

### SUMMARY

However, in the semiconductor device disclosed in Patent Document 1, since the second slits overlap the first slits in plan view, the upper surface of the semiconductor substrate is exposed from the second slits, necessitating a silicide block film to cover the exposed portion. Consequently, forming the silicide block film results in an increase in the electrical resistance value of the gate electrode. Other problems and novel features will become apparent from the description of this specification and the accompanying drawings.

A semiconductor device of this disclosure includes a semiconductor substrate having an upper surface, a first source layer formed in the semiconductor substrate and disposed at the upper surface, a first drain layer formed in the semiconductor substrate and disposed at the upper surface so as to be spaced apart from the first source layer in a first direction, a first drain insulating film formed on the upper surface and located between the first source layer and the first drain layer in the first direction, a first gate insulating film formed on the upper surface between the first drain insulating film and the first source layer in the first direction, and a first gate electrode formed on the first gate insulating film and on the first drain insulating film. The first drain insulating film has a first end facing the first source layer and a second end facing the first drain layer in the first direction. In the first gate electrode, at least one slit is formed that penetrates through the first gate electrode and overlaps the first drain insulating film in plan view while not overlapping the first gate insulating film. The slit has a third end in the first direction and a fourth end located on the opposite side of the third end and spaced from the first source layer than the third end. The third end is located between the second end and the boundary between the first drain insulating film and the first gate electrode in the first direction.

According to the semiconductor device of this disclosure, it is possible to reduce the area ratio of the gate electrode while reducing the electrical resistance value of the gate electrode.

### BRIEF DESCRIPTION OF THE DRAWINGS

FIG. 1 is a plan view of a semiconductor device DEV1.

FIG. 2 is a cross-sectional view of the semiconductor device DEV1 in II-II in FIG. 1.

FIG. 3 is a cross-sectional view of the semiconductor device DEV1 in III-III in FIG. 1.

FIG. 4 is a plan view of the semiconductor device DEV1 according to a first modified example.

FIG. 5 is a plan view of the semiconductor device DEV1 according to a second modified example.

FIG. 6 is a plan view of the semiconductor device DEV1 according to a third modified example.

FIG. 7 is a plan view of the semiconductor device DEV1 according to a fourth modified example.

FIG. 8 is a cross-sectional view of the semiconductor device DEV1 in VIII-VIII in FIG. 7 according to the fourth modified example.

FIG. 9 is a cross-sectional view of the semiconductor device DEV1 in IX-IX in FIG. 7 according to the fourth modified example.

FIG. 10 is a process diagram of manufacturing the semiconductor device DEV1.

FIG. 11 is a cross-sectional view explaining the ion implantation step S2.

FIG. 12 is a cross-sectional view explaining the drain insulating film formation step S3.

FIG. 13 is a cross-sectional view explaining the gate insulating film formation step S4.

FIG. 14 is a cross-sectional view explaining the gate electrode formation step S5.

FIG. 15A is a first cross-sectional view explaining the ion implantation step S6.

FIG. 15B is a second cross-sectional view explaining the ion implantation step S6.

FIG. 16 is a cross-sectional view explaining the interlayer insulating film formation step S7.

FIG. 17 is a cross-sectional view explaining the element isolation film formation step S8.

FIG. 18 is a cross-sectional view explaining the contact plug formation step S9.

FIG. 19 is an enlarged plan view of a semiconductor device DEV3.

FIG. 20A is a first schematic diagram explaining the relationship between the width of a slit SLT and the withstand voltage.

FIG. 20B is a second schematic diagram explaining the relationship between the width of the slit SLT and the withstand voltage.

FIG. 21 is a plan view of a semiconductor device DEV2.

FIG. 22 is a cross-sectional view of the semiconductor device DEV2 in XXII-XXII in FIG. 21.

FIG. 23 is a plan view of the semiconductor device DEV2 according to a first modified example.

FIG. 24 is a plan view of the semiconductor device DEV2 according to a second modified example.

FIG. 25A is the first schematic diagram explaining the effect of the semiconductor device DEV2.

FIG. 25B is a second schematic diagram explaining the effect of the semiconductor device DEV2.

### DETAILED DESCRIPTION

The details of the embodiment of this disclosure will be described with reference to the drawings. In the following drawings, the same reference numerals are used for the same or corresponding parts, and redundant explanations are not repeated.

### First Embodiment

The semiconductor device DEV1 according to the first embodiment will be described.

### Configuration of Semiconductor Device DEV1

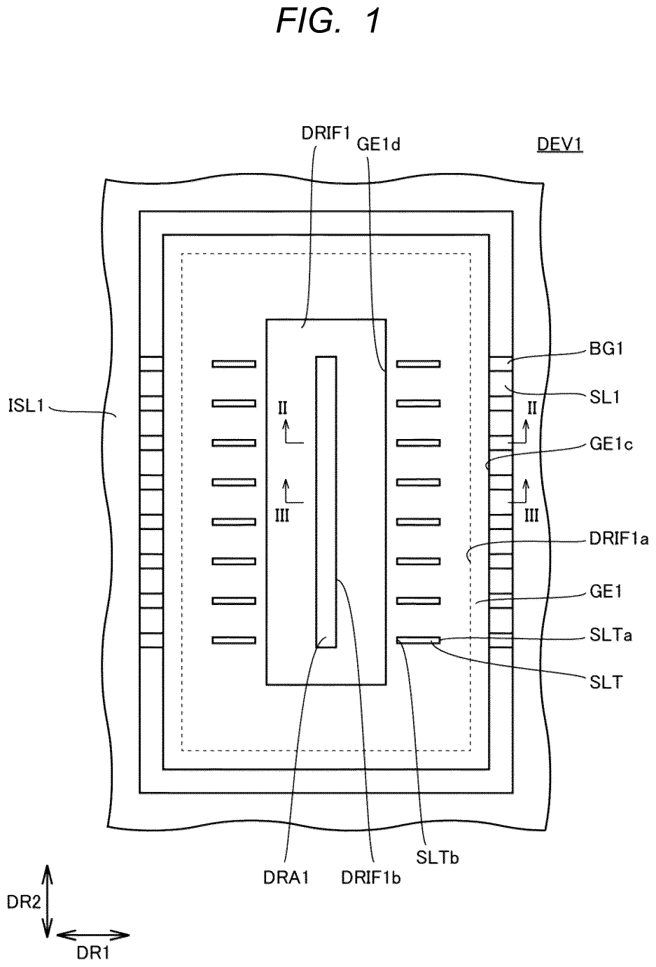

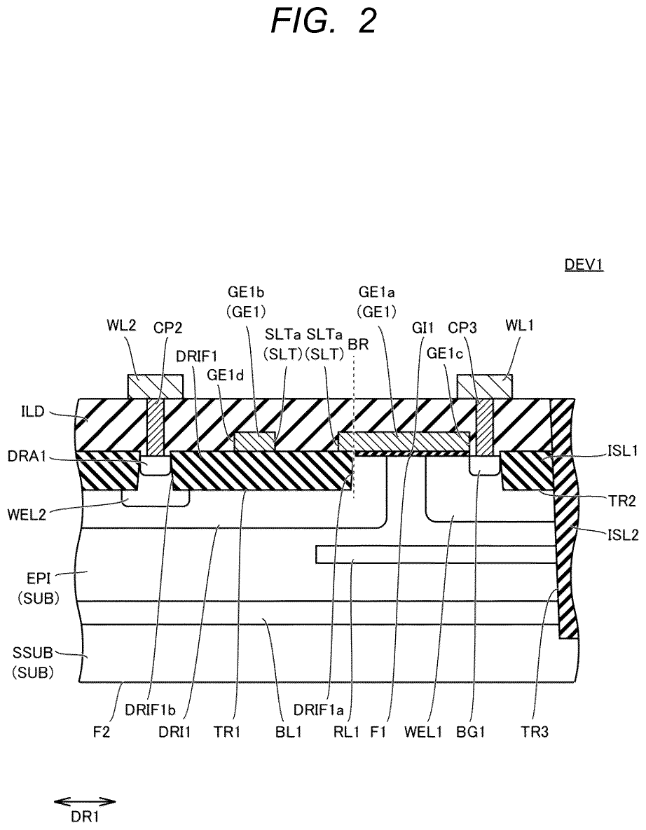

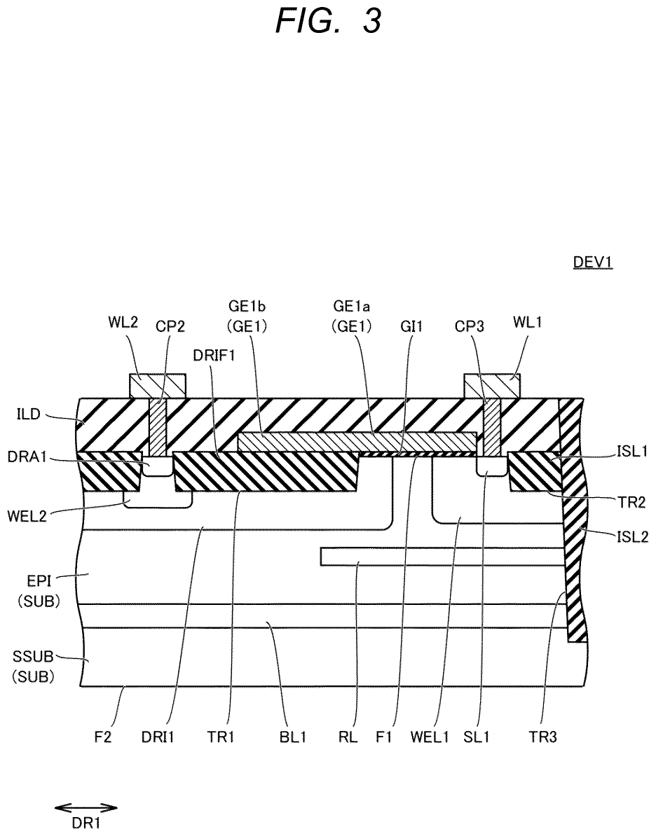

As shown in FIGS. 1, 2, and 3, the semiconductor device DEV1 includes a semiconductor substrate SUB, a drain insulating film DRIF1, a gate insulating film GI1, a gate electrode GE1, and an element isolation film ISL1.

The semiconductor substrate SUB is formed of, for example, single crystal silicon. The semiconductor substrate SUB has an upper surface F1 and a lower surface F2 located on the opposite side of the upper surface F1. The semiconductor substrate SUB includes, for example, a support substrate SSUB and an epitaxial layer EPI formed on the upper surface of the support substrate SSUB. The lower surface of the support substrate SSUB forms the lower surface F2. The upper surface of the epitaxial layer EPI forms the upper surface F1.

The semiconductor substrate SUB includes a source layer SL1 and a drain layer DRA1. The source layer SL1 is formed in the semiconductor substrate SUB (epitaxial layer EPI) and disposed at the upper surface F1. The drain layer DRA1 is formed in the semiconductor substrate SUB (epitaxial layer EPI) and disposed at the upper surface F1. The drain layer DRA1 is spaced apart from the source layer SL1 in a first direction DR1.

The semiconductor substrate SUB includes a well layer WEL1 and a well layer WEL2. The well layer WELL is formed in the semiconductor substrate SUB (epitaxial layer EPI) and disposed at the upper surface F1 to surround the source layer SL1. The well layer WEL2 is formed in the semiconductor substrate SUB (epitaxial layer EPI) and disposed at the upper surface F1 to surround the drain layer DRA1. The semiconductor substrate SUB includes a back gate layer BG1. The back gate layer BG1 is formed in the semiconductor substrate SUB (epitaxial layer EPI) and disposed at the upper surface F1 to be surrounded by the well layer WEL1. The back gate layer BG1 and the source layer SL1 are alternately arranged in a second direction DR2 perpendicular to the first direction DR1 in plan view. The semiconductor substrate SUB includes a drift layer DRI1. The drift layer DRI1 is formed in the semiconductor substrate SUB (epitaxial layer EPI) and disposed at the upper surface F1 to surround the well layer WEL2.

The conductivity type of the source layer SL1, the drain layer DRA1, the well layer WEL2, and the drift layer DRI1 is the first conductivity type. On the other hand, the conductivity type of the epitaxial layer EPI, the well layer WEL1, and the back gate layer BG1 is the second conductivity type opposite to the first conductivity type. For example, the first conductivity type is n-type, and the second conductivity type is p-type.

The semiconductor substrate SUB includes a buried layer BL1 and a RESURF (Reduced Surface Field) layer RL1. The buried layer BL1 is formed in the epitaxial layer EPI and disposed on the support substrate SSUB. The conductivity type of the buried layer BLI is the first conductivity type. The RESURF layer RL1 is formed in the epitaxial layer EPI. The RESURF layer RL1 overlaps the well layer WEL1 and the drift layer DRI1 in plan view. The RESURF layer RL1 is located between the well layer WEL1 and the buried layer BL1 and between the drift layer DRI1 and the buried layer BL1 in the thick direction of the epitaxial layer EPI perpendicular to the first direction DR1 and the second direction DR2. The conductivity type of the RESURF layer RL1 is the second conductivity type.

A trench TR1 is formed at the upper surface F1. The trench TR1 extends toward the lower surface F2. The trench TR1 is located between the source layer SL1 and the drain layer DRA1 in the first direction DR1. In plan view, the trench TR1 surrounds the drain layer DRA1. The drain insulating film DRIF1 is formed in the trench TR1. That is, the drain insulating film DRIF1 and the trench TR1 are formed by the STI (Shallow Trench Isolation) method. From another perspective, the drain insulating film DRIF1 is located between the source layer SL1 and the drain layer DRA1 in the first direction DR1. The drain insulating film DRIF1 is formed of, for example, silicon oxide. Note that the drain insulating film DRIF1 may be formed at the upper surface F1 by the LOCOS (Local Oxidation of Silicon) method without forming the trench TR1 at the upper surface F1.

The drain insulating film DRIF1 has an end DRIF1a facing the source layer SL1 and an end DRIF1b facing the drain layer DRA1 in the first direction DR1. In plan view, the end DRIF1a and the end DRIF1b are linear in the second direction DR2.

The gate insulating film GI1 is formed on the upper surface F1, located between the trench TR1 (drain insulating film DRIF1) and the source layer SL1 in the first direction DR1. The gate insulating film GI1 is formed of, for example, silicon oxide. The gate electrode GE1 is formed on the gate insulating film GI1 and the drain insulating film DRIF1. The gate electrode GE1 is formed of, for example, polycrystalline silicon containing a dopant. The gate electrode GE1, the gate insulating film GI1, the source layer SL1, the well layer WEL1, the epitaxial layer EPI, the drift layer DRI1, the well layer WEL2, and the drain layer DRA1 configure the first LDMOS (Laterally Diffused Metal Oxide Semiconductor) transistor.

The gate electrode GE1 has a first portion GE1a and a second portion GE1b. The first portion GE1a is located on the gate insulating film GI1. The second portion GE1b is located on the drain insulating film DRIF1. A plurality of slits SLT are formed in the second portion GE1b. At least one slit SLT may be formed. The slit SLT has an end SLTa and an end SLTb, which is located on the opposite side of the end SLTa and is spaced apart from the source layer SL1 than the end SLTa in the first direction DR1. In plan view, the end SLTa is located between the end DRIF1b and a boundary BR between the drain insulating film DRIF1 and the gate insulating film GI1. In other words, in plan view, the slit SLT overlaps the drain insulating film DRIF1 but does not overlap the gate insulating film GI1.

The slit SLT penetrates through the second portion GE1b. The slit SLT has a rectangular shape consisting of a pair of sides parallel to the first direction DR1 and a pair of sides parallel to the second direction DR2. The slit SLT extends in the first direction DR1. That is, the width of the slit SLT in the first direction DR1 is greater than the width of the slit SLT in the second direction DR2. The plurality of slits SLT are arranged in a row in the second direction DR2 with an interval between two slits SLT adjacent to each other. The width of the slit SLT in the short direction, that is, the width of the slit SLT in the second direction DR2, is, for example, less than or equal to √3 times the thickness of the drain insulating film DRIF1.

The slit SLT is aligned with the back gate layer BG1 in the first direction DR1 in plan view. In this case, the slit SLT is not aligned with the source layer SL1 in the first direction DR1 in plan view.

A trench TR2 is formed at the upper surface F1. The trench TR2 extends toward the lower surface F2. In plan view, the trench TR2 surrounds the first LDMOS transistor. The element isolation film ISL1 is formed in the trench TR2. That is, the element isolation film ISL1 and the trench TR2 are formed by the STI method. Thus, the first LDMOS transistor is insulated and isolated from other elements. Note that the element isolation film ISL1 may be formed at the upper surface F1 by the LOCOS method without forming the trench TR2 at the upper surface F1. The element isolation film ISL1 is formed of, for example, silicon oxide.

The semiconductor device DEV1 includes an interlayer insulating film ILD, a contact plug CP1, a contact plug CP2, and a contact plug CP3. The interlayer insulating film ILD is formed of, for example, silicon oxide. The interlayer insulating film ILD is formed on the upper surface F1 to cover the drain insulating film DRIF1, the gate electrode GE1, and the element isolation film ISL1.

The contact plug CP1, the contact plug CP2, and the contact plug CP3 are formed in the interlayer insulating film ILD. The contact plug CP1 is located on the source layer SL1, the contact plug CP2 is located on the drain layer DRA1, and the contact plug CP3 is located on the back gate layer BG1. The contact plug CP1, the contact plug CP2, and the contact plug CP3 are formed of, for example, tungsten. A contact plug not shown in the figures is also formed in the interlayer insulating film ILD on the gate electrode GE1.

A trench TR3 is formed at the upper surface of the interlayer insulating film ILD. The trench TR3 extends toward the lower surface F2. The trench TR3 penetrates through the interlayer insulating film ILD and the element isolation film ISL1. The bottom surface of the trench TR3 reaches the support substrate SSUB. The semiconductor device DEV1 includes an element isolation film ISL2. The element isolation film ISL2 is formed in the trench TR3. The element isolation film ISL2 is formed of silicon oxide. The trench TR3 and the element isolation film ISL2 are formed by the DTI (Deep Trench Isolation) method.

The semiconductor device DEV1 includes a wiring WL1 and a wiring WL2. The wiring WL1 and the wiring WL2 are formed on the interlayer insulating film ILD. The wiring WL1 and the wiring WL2 are formed of, for example, aluminum or an aluminum alloy. The wiring WL1 is electrically connected to the source layer SL1 via the contact plug CP1 and to the back gate layer BG1 via the contact plug CP3. The wiring WL2 is electrically connected to the drain layer DRA1 via the contact plug CP2. The semiconductor device DEV1 further includes wiring not shown in the figures. The wiring not shown is electrically connected to the gate electrode GE1 via a contact plug not shown in the figures, which is formed in the interlayer insulating film ILD to be located on the gate electrode GE1.

### First Modified Example

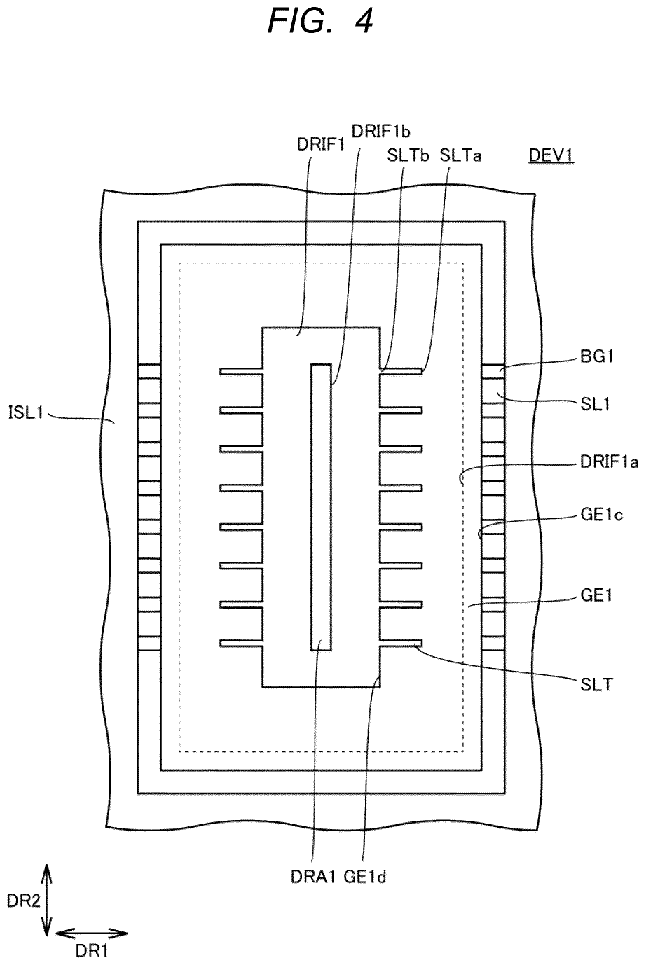

As shown in FIG. 4, the gate electrode GE1 has an end GE1c and an end GE1d, which is spaced apart from the source layer SL1 than the end GE1c in the first direction DR1. The slit SLT may extend such that the end SLTb reaches the end GE1d.

### Second Modified Example

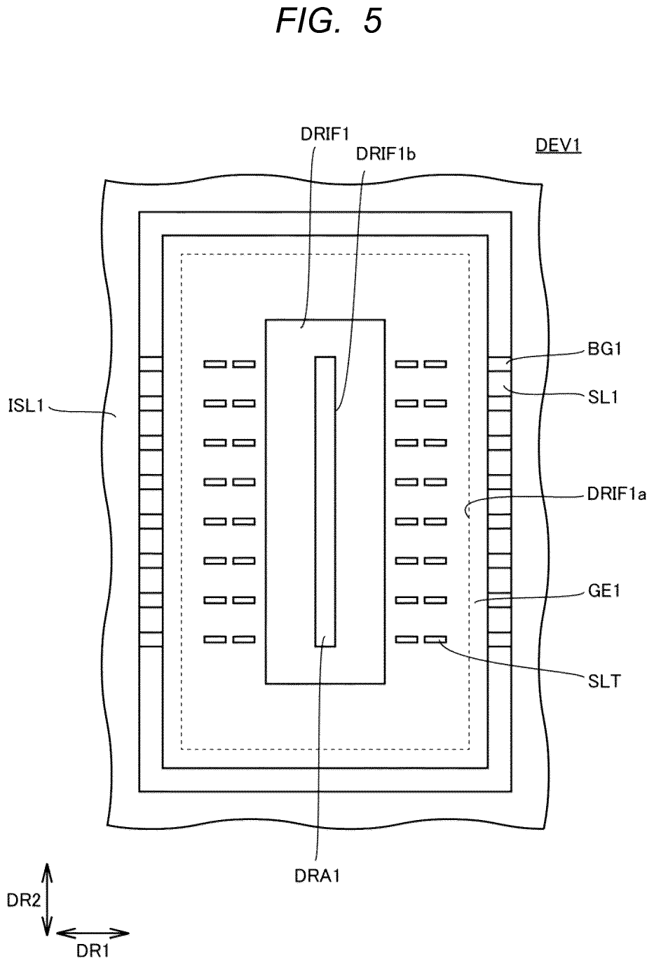

As shown in FIG. 5, the plurality of slits SLT may be arranged in plurality of rows in the second direction DR2. The plurality of slits SLT arranged in rows in the second direction DR2 have intervals between two slits SLT adjacent to each other. In the example shown in FIG. 5, the plurality of slits SLT are arranged in two rows in the second direction DR2 with intervals between two slits SLT adjacent to each other. The plurality of rows are arranged with intervals in the first direction DR1.

### Third Modified Example

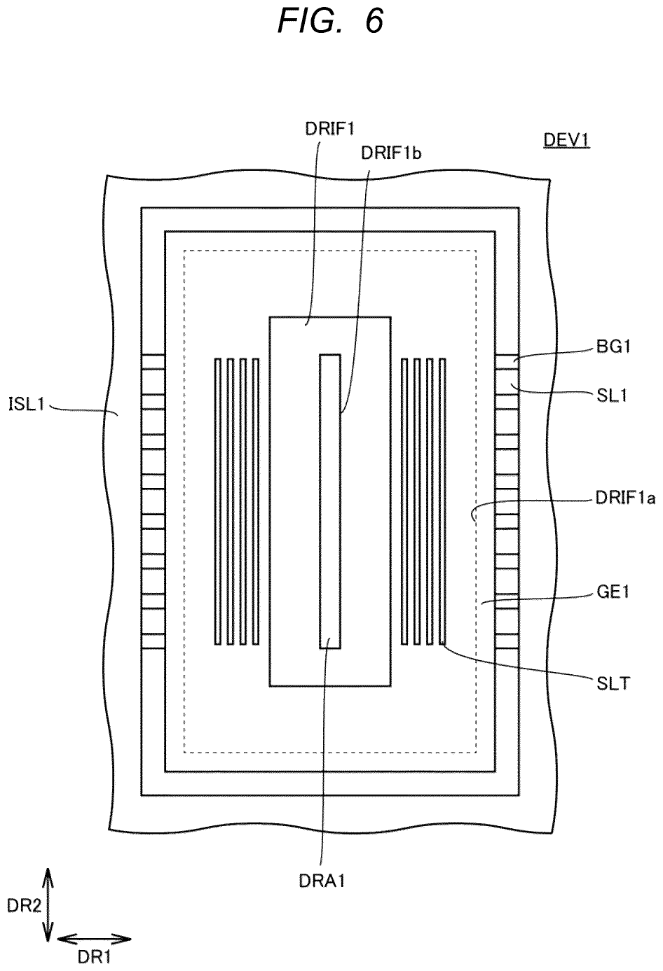

As shown in FIG. 6, the slit SLT may extend in the second direction DR2. That is, the width of the slit SLT in the first direction DR1 may be smaller than the width of the slit SLT in the second direction DR2. In this case, the short direction of the slit SLT is the first direction DR1. In this case, the plurality of slits SLT may be arranged in the first direction DR1 with intervals between two slits SLT adjacent to each other.

### Fourth Modified Example

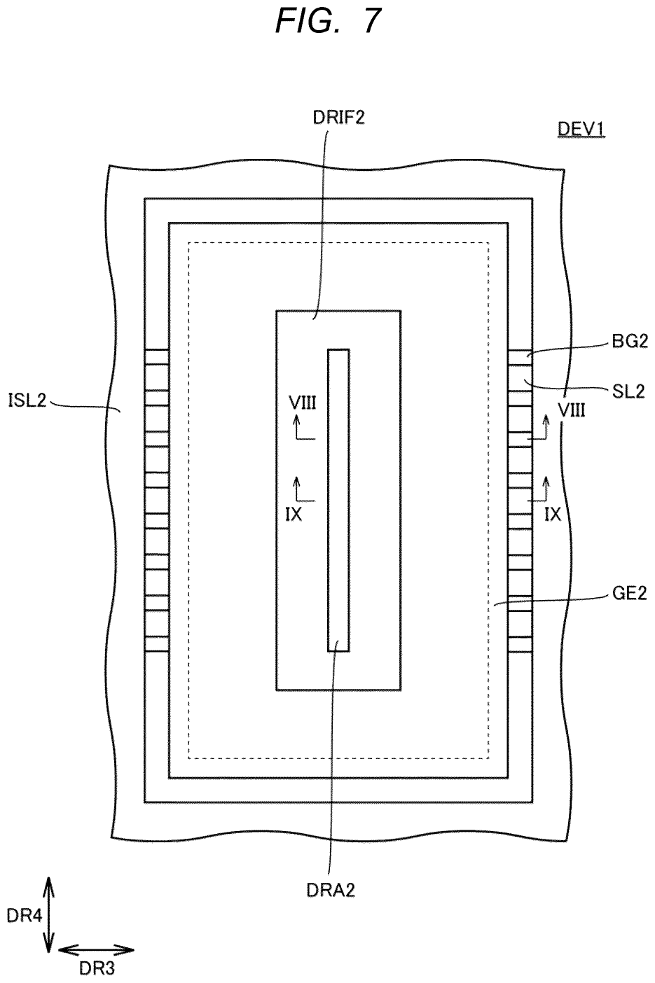

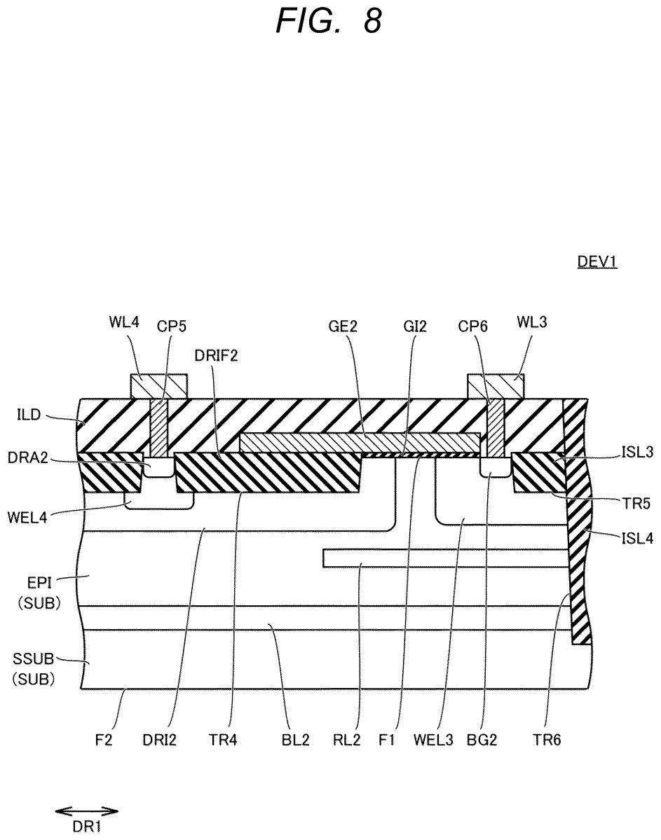

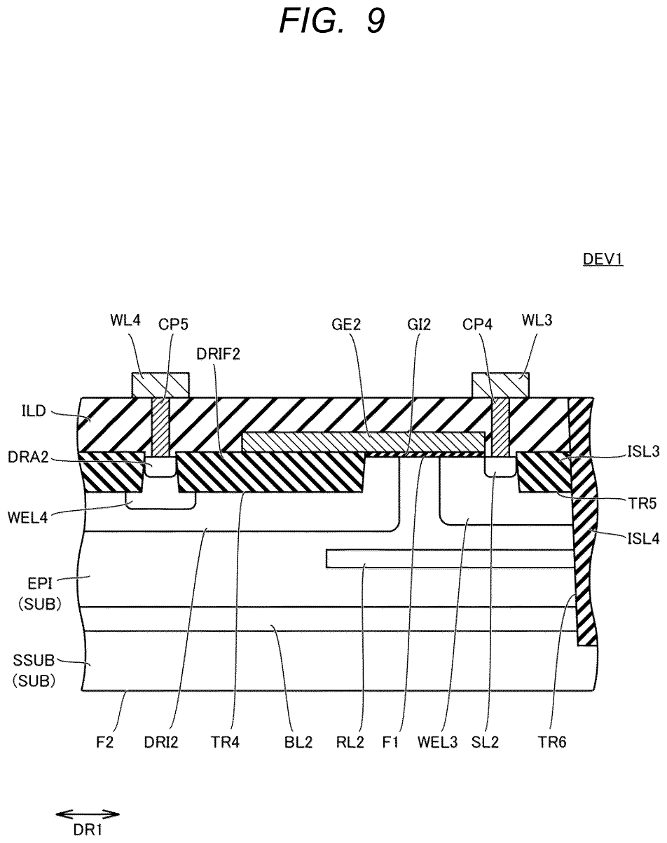

As shown in FIGS. 7, 8, and 9, the semiconductor device DEV1 may further include a second LDMOS transistor separate from the first LDMOS transistor. The second LDMOS transistor has a similar structure to the first LDMOS transistor except that no slit is formed in a gate electrode GE2. More specifically, the semiconductor substrate SUB includes a source layer SL2, a drain layer DRA2, a well layer WEL3, a well layer WEL4, a back gate layer BG2, a drift layer DRI2, a buried layer BL2, and a RESURF layer RL2.

The source layer SL2 is formed in the semiconductor substrate SUB and is located at the upper surface F1. The drain layer DRA2 is also formed in the semiconductor substrate SUB and is formed at the upper surface F1. In plan view, the drain layer DRA2 is spaced apart from the source layer SL2. In plan view, the drain layer DRA2 is arranged in a third direction DR3 with a space between the drain layer DRA2 and the source layer SL2. The well layer WEL3 is formed in the semiconductor substrate SUB and is located at the upper surface F1 to surround the source layer SL2. The well layer WEL4 is formed in the semiconductor substrate SUB and is located at the upper surface F1 to surround the drain layer DRA2. The drift layer DRI2 is formed in the semiconductor substrate SUB and is located at the upper surface F1 to surround the well layer WEL4. The back gate layer BG2 is formed in the semiconductor substrate SUB and is located at the upper surface F1 to be surrounded by the well layer WEL3. The back gate layer BG2 and the source layer SL2 are alternately arranged in a fourth direction DR4 perpendicular to the third direction DR3 in plan view.

The buried layer BL2 is formed in the epitaxial layer EPI and is located on the support substrate SSUB. The RESURF layer RL2 is formed in the epitaxial layer EPI and overlaps the well layer WEL3 and the drift layer DRI2 in plan view. The RESURF layer RL2 is located between the well layer WEL3 and the buried layer BL2, and between the drift layer DRI2 and the buried layer BL2 in the thick direction of the epitaxial layer EPI, which is perpendicular to the third direction DR3 and the fourth direction DR4. The conductivity type of the source layer SL2, the drain layer DRA2, the well layer WEL4, the drift layer DRI2, and the buried layer BL2 are the first conductivity type. The conductivity type of the well layer WEL3, the back gate layer BG2, and the RESURF layer RL2 are the second conductivity type.

The semiconductor device DEV1 further includes a drain insulating film DRIF2, a gate insulating film GI2, the gate electrode GE2, an element isolation film ISL3, an element isolation film ISL4, a contact plug CP4, a contact plug CP5, and a contact plug CP6.

A trench TR4 is formed at the upper surface F1. The trench TR4 is located between the source layer SL2 and the drain layer DRA2 in the third direction DR3. In plan view, the trench TR4 surrounds the drain layer DRA2. The drain insulating film DRIF2 is formed in the trench TR4. The drain insulating film DRIF2 is formed of, for example, silicon oxide. The gate insulating film GI2 is formed on the upper surface F1, located between the trench TR4 (drain insulating film DRIF2) and the source layer SL2 in the third direction DR3. The gate insulating film GI2 is formed of, for example, silicon oxide. The gate electrode GE2 is formed on the gate insulating film GI2 and on the drain insulating film DRIF2. The gate electrode GE2 is formed of, for example, polycrystalline silicon containing a dopant. The gate electrode GE2, the gate insulating film GI2, the source layer SL2, the well layer WEL3, the epitaxial layer EPI, the drift layer DRI2, the well layer WEL4, and the drain layer DRA2 configure the second LDMOS transistor.

A trench TR5 is formed at the upper surface F1. The element isolation film ISL3 is formed in the trench TR5. The trench TR5 extends toward the lower surface F2. In plan view, the trench TR4 surrounds the second LDMOS transistor. The element isolation film ISL3 is formed in the trench TR5. By the element isolation film ISL3, the second LDMOS transistor is insulated and isolated from other elements. The element isolation film ISL3 is formed of, for example, silicon oxide.

The contact plug CP4, the contact plug CP5, and the contact plug CP6 are formed in the interlayer insulating film ILD. The contact plug CP4 is located on the source layer SL2, the contact plug CP5 is located on the drain layer DRA2, and the contact plug CP3 is located on the back gate layer BG2. The contact plug CP4, the contact plug CP5, and the contact plug CP6 are formed of, for example, tungsten. In the interlayer insulating film ILD, a contact plug not shown in the figures is also formed on the gate electrode GE2.

A trench TR6 is formed at the upper surface of the interlayer insulating film ILD. The trench TR6 extends toward the lower surface F2. The trench TR6 penetrates through the interlayer insulating film ILD and the element isolation film ISL3. The bottom of the trench TR6 reaches the support substrate SSUB. The element isolation film ISL4 is formed in the trench TR6. The element isolation film ISL4 is formed of silicon oxide. The trench TR6 and the element isolation film ISL4 are formed by the DTI method.

The semiconductor device DEV1 further includes a wiring WL3 and a wiring WL4. The wiring WL3 and the wiring WL4 are formed on the interlayer insulating film ILD. The wiring WL3 is electrically connected to the source layer SL2 via the contact plug CP4 and to the back gate layer BG2 via the contact plug CP6. The wiring WL4 is electrically connected to the drain layer DRA2 via the contact plug CP5. The wiring WL3 and the wiring WL4 are formed of, for example, aluminum or an aluminum alloy. The semiconductor device DEV1 further includes a wiring not shown in the figures. The wiring not shown is electrically connected to the gate electrode GE2 via the contact plug not shown in the figures, which is formed in the interlayer insulating film ILD to be located on the gate electrode GE2.

Thus, the second LDMOS transistor has a structure similar to the first LDMOS transistor, but the second LDMOS transistor differs from the first LDMOS transistor in that no slit is formed in the gate electrode GE2.

### Manufacturing Method of Semiconductor Device DEV1

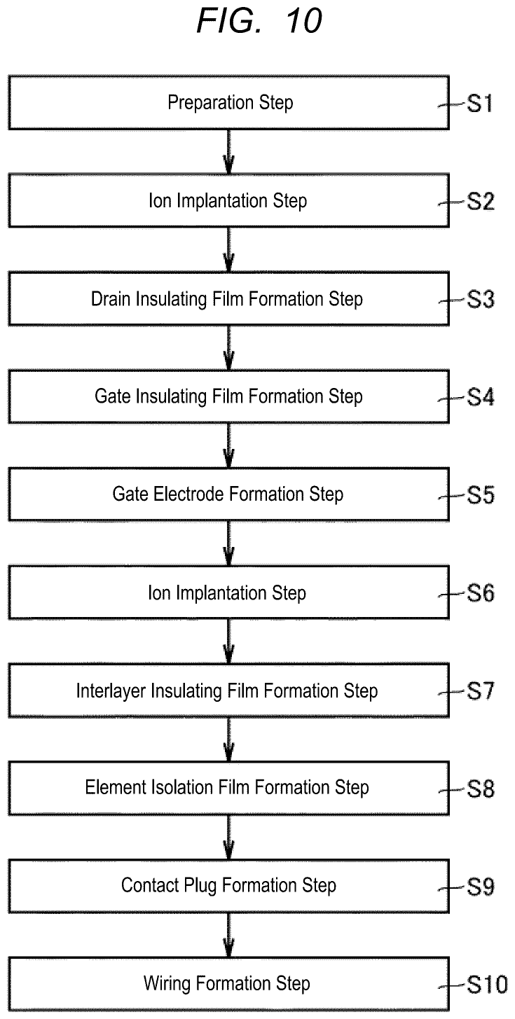

As shown in FIG. 10, the manufacturing method of the semiconductor device DEV1 includes a preparation step S1, an ion implantation step S2, a drain insulating film formation step S3, a gate insulating film formation step S4, a gate electrode formation step S5, and an ion implantation step S6. Additionally, the manufacturing method of the semiconductor device DEV1 includes an interlayer insulating film formation step S7, an element isolation film formation step S8, a contact plug formation step S9, and a wiring formation step S10.

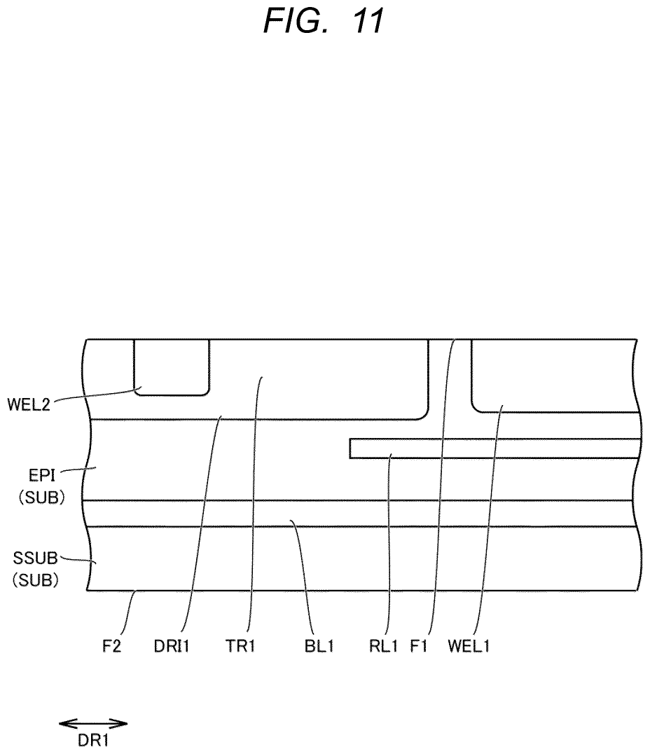

In the preparation step S1, the semiconductor substrate SUB having the support substrate SSUB and the epitaxial layer EPI formed on the support substrate SSUB is prepared. As shown in FIG. 11, in the ion implantation step S2, the well layer WEL1, the well layer WEL2, the drift layer DRI1, the buried layer BL1, and the RESURF layer RL1 are formed by ion implantation.

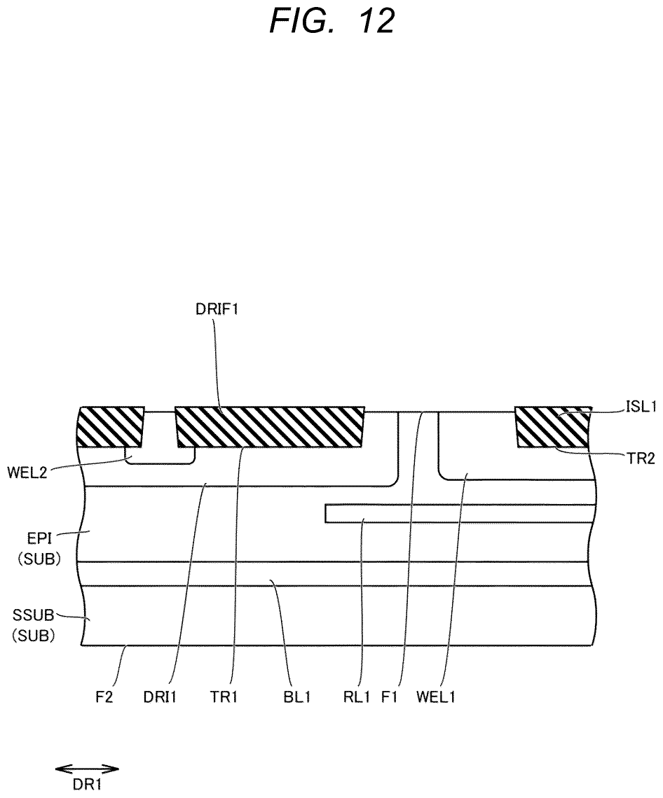

As shown in FIG. 12, in the drain insulating film formation step S3, after the trench TR1 is formed, the drain insulating film DRIF1 is formed. Additionally, in the drain insulating film formation step S3, when forming the trench TR1, the trench TR2 is also formed, and when the drain insulating film DRIF1 is formed, the element isolation film ISL1 is also formed.

In the drain insulating film formation step S3, firstly, dry etching is performed on the semiconductor substrate SUB through the opening of a hard mask formed on the upper surface F1, thereby forming the trench TR1 and the trench TR2 at the upper surface F1. Secondly, for example, by the CVD (Chemical Vapor Deposition) method, the constituent material of the drain insulating film DRIF1 is embedded in the trench TR1, the constituent material of the element isolation film ISL1 is embedded in the trench TR2, and the constituent material of the drain insulating film DRIF1 (element isolation film ISL1) is formed on the hard mask. Thirdly, the constituent material of the drain insulating film DRIF1 (element isolation film ISL1) formed outside the trench TR1 and the trench TR2 is removed by the CMP (Chemical Mechanical Polishing) method or etch-back. As a result, the drain insulating film DRIF1 and an element isolation film IF1 are formed.

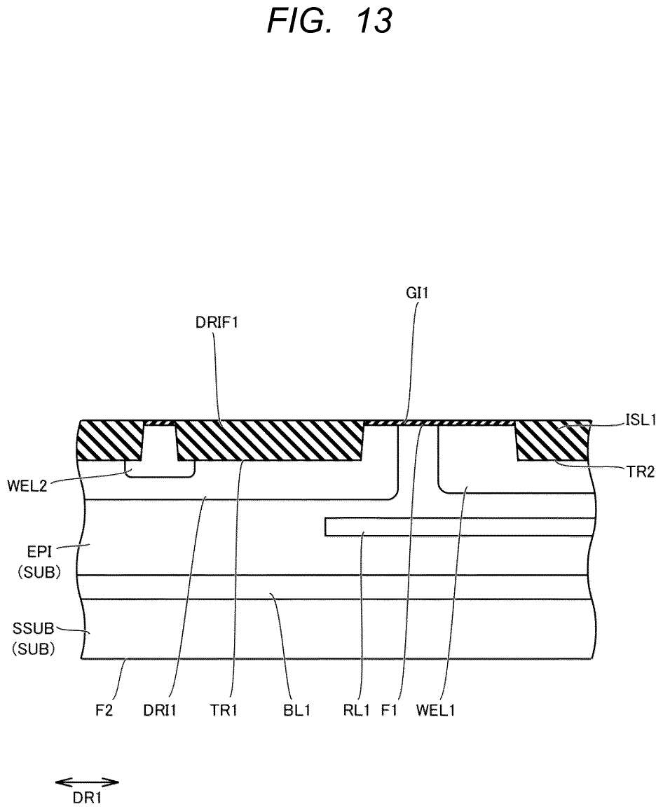

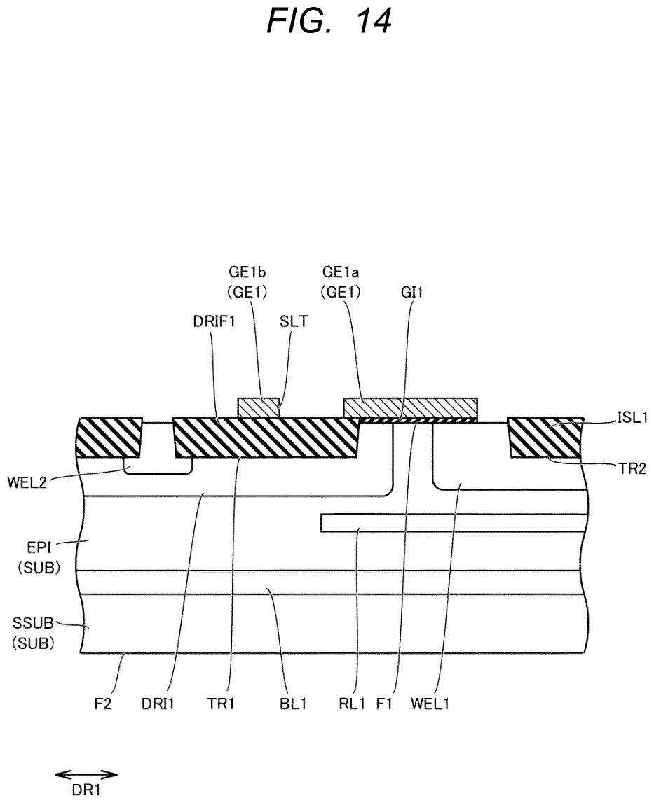

As shown in FIG. 13, in the gate insulating film formation step S4, for example, by thermal oxidation, the gate insulating film GI1 is formed on the upper surface F1. As shown in FIG. 14, in the gate electrode formation step S5, the gate electrode GE1 is formed on the gate insulating film GI1 and on the drain insulating film DRIF1. In the gate electrode formation step S5, firstly, the constituent material of the gate electrode GE1 is deposited on the gate insulating film GI1 and on the drain insulating film DRIF1. Secondly, a resist pattern is formed on the constituent material of the gate electrode GE1. Thirdly, dry etching is performed on the constituent material of the gate electrode GE1 through the opening of the resist pattern, thereby patterning the constituent material of the gate electrode GE1. As a result, the gate electrode GE1 is formed. Note that during dry etching, the gate insulating film GI1 located outside the gate electrode GE1 is also removed.

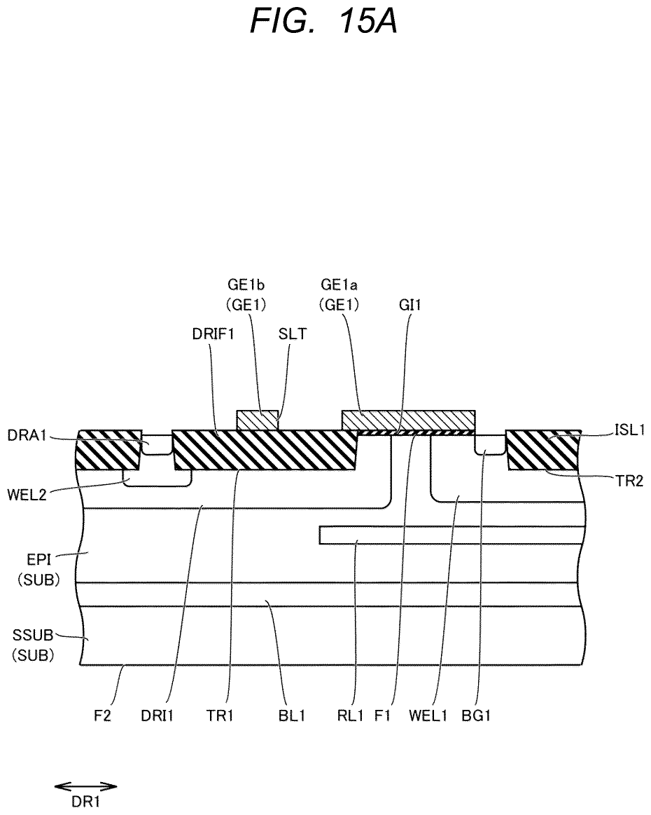

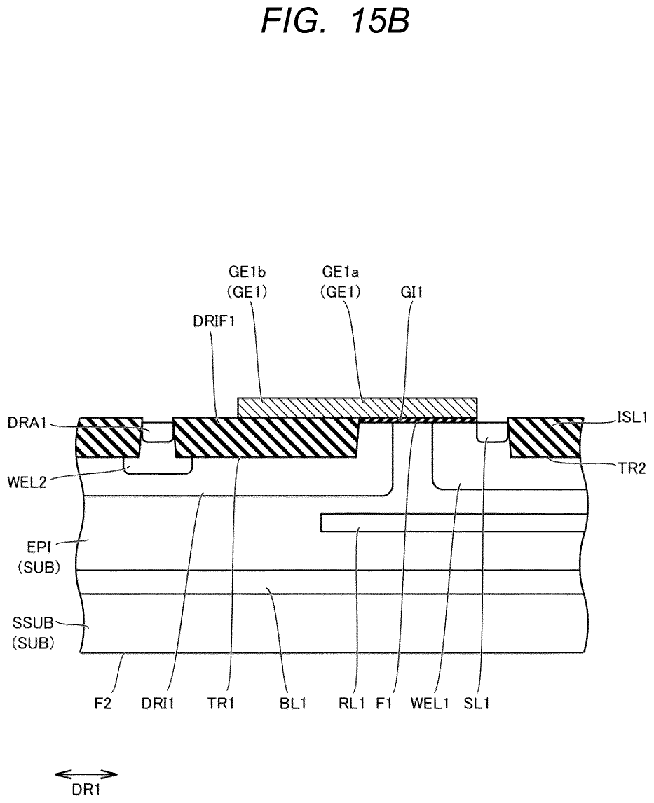

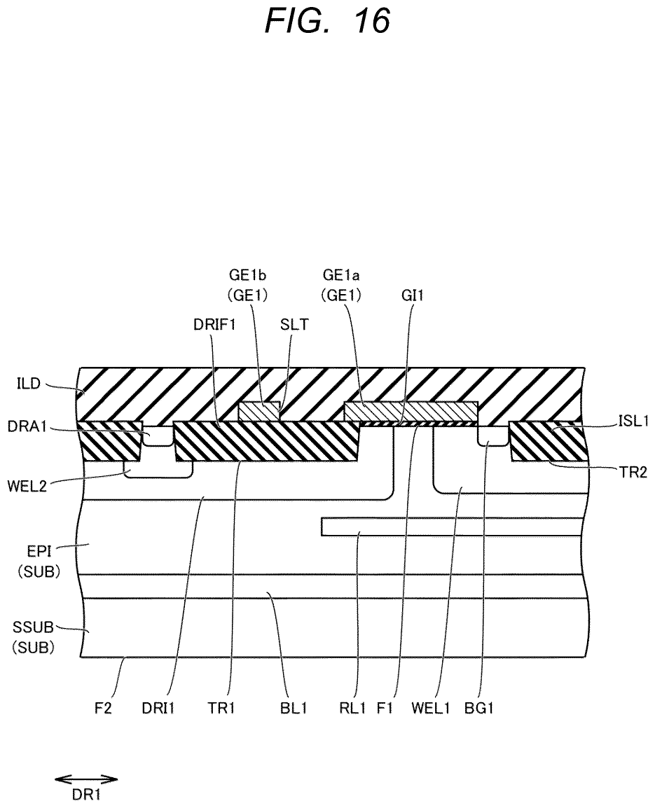

As shown in FIGS. 15A and 15B, in the ion implantation step S6, the source layer SL1, the drain layer DRA1, and the back gate layer BG1 are formed through ion implantation. After the formation of the source layer SL1, the drain layer DRA1, and the back gate layer BG1, a silicide layer is formed on the upper surfaces of the source layer SL1, the drain layer DRA1, the back gate layer BG1, and the gate electrode GE1. As shown in FIG. 16, in the interlayer insulating film formation step S7, the interlayer insulating film ILD is formed on the semiconductor substrate SUB to cover the drain insulating film DRIF1, the element isolation film ISL1, and the gate electrode GE1. In the interlayer insulating film formation step S7, firstly, the interlayer insulating film ILD is formed, for example, by the CVD method. Secondly, the upper surface of the interlayer insulating film ILD is planarized, for example, by the CMP method.

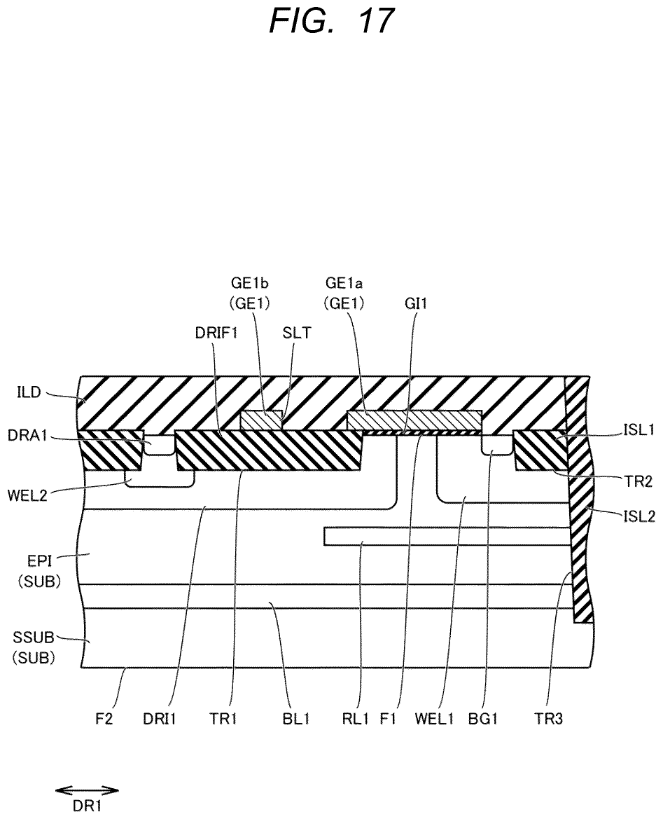

As shown in FIG. 17, in the element isolation film formation step S8, after the formation of the trench TR3, the element isolation film ISL2 is formed. In the element isolation film formation step S8, dry etching is performed on the interlayer insulating film ILD, the element isolation film ISL1, and the semiconductor substrate SUB through the openings of the resist pattern formed on the interlayer insulating film ILD, thereby forming the trench TR3. Secondly, for example, by the CVD method, the constituent material of the element isolation film ISL2 is embedded in the trench TR3, and the constituent material of the element isolation film ISL2 is formed on the interlayer insulating film ILD. Thirdly, the constituent material of the element isolation film ISL2 formed outside the trench TR3 is removed, for example, by the CMP method.

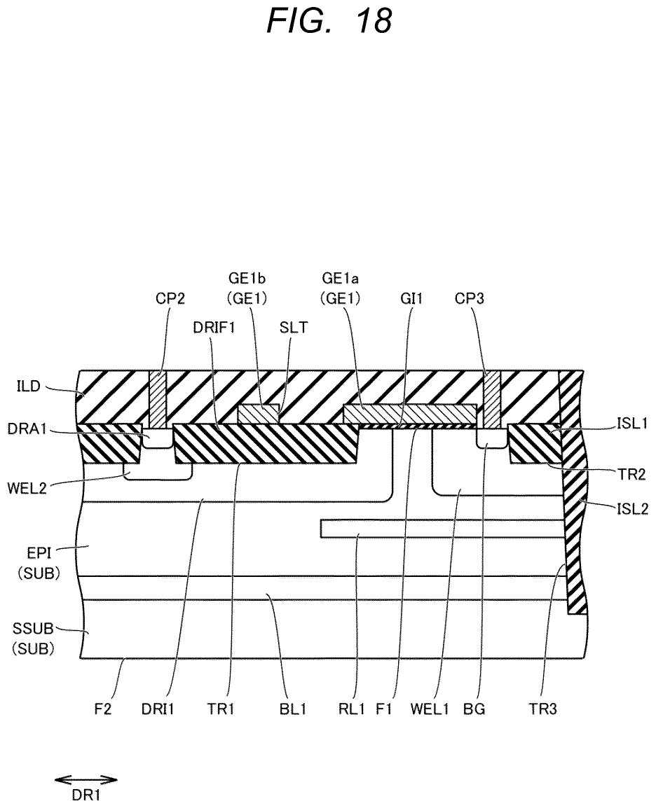

As shown in FIG. 18, in the contact plug formation step S9, the contact plug CP1, the contact plug CP2, and the contact plug CP3 are formed in the interlayer insulating film ILD. In the contact plug formation step S9, firstly, dry etching is performed on the interlayer insulating film ILD through the openings of the resist pattern formed on the interlayer insulating film ILD, thereby forming contact holes in the interlayer insulating film ILD located on the source layer SL1, the drain layer DRA1, and the back gate layer BG1. Secondly, for example, by the CVD method, the constituent materials of the contact plug CP1, the contact plug CP2, and the contact plug CP3 are embedded in the contact holes, and the constituent materials of the contact plug CP1, the contact plug CP2, and the contact plug CP3 are formed on the interlayer insulating film ILD. Thirdly, the constituent materials of the contact plug CP1, the contact plug CP2, and the contact plug CP3 formed outside the contact holes are removed, for example, by the CVD method.

In the wiring formation step S10, the wiring WL1 and the wiring WL2 are formed on the interlayer insulating film ILD. In the wiring formation S10, firstly, step the constituent materials of the wiring WL1 and the wiring WL2 are formed on the interlayer insulating film ILD, for example, by sputtering. Secondly, a resist pattern is formed on the constituent materials of the wiring WL1 and the wiring WL2. Thirdly, dry etching is performed on the constituent materials of the wiring WL1 and the wiring WL2 through the openings of the resist pattern, thereby patterning the constituent materials of the wiring WL1 and the wiring WL2 and forming the wiring WL1 and the wiring WL2. As a result, the structure of the semiconductor device DEV1 shown in FIGS. 1 to 3 is formed.

### Effects of Semiconductor Device DEV1

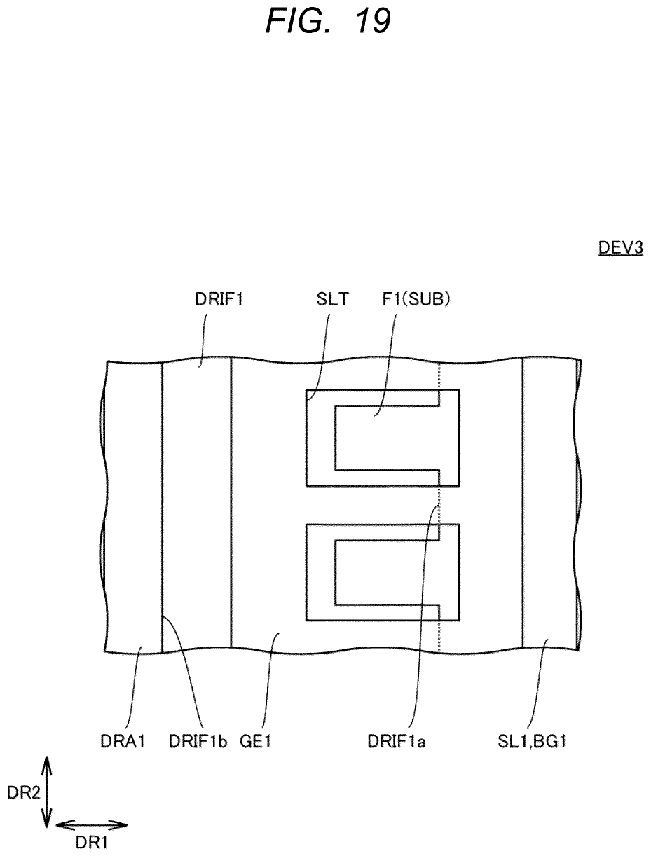

As shown in FIG. 19, in the semiconductor device DEV3 according to a comparative example, plurality of slits extending from the end DRIF1a to the end DRIF1b are formed in the drain insulating film DRIF1. The plurality of slits are arranged in the second direction DR2 with intervals. In the semiconductor device DEV3, the plurality of slits SLT are formed to overlap the upper surface F1 located between two slits adjacent to each other in plan view.

If the area ratio of the gate electrode GE1 (the ratio of the area of the gate electrode GE1 to the chip area) is too large, the shape of the gate electrode GE1 becomes tapered when the constituent material of the gate electrode GE1 is patterned by dry etching to form the gate electrode GE1. In the semiconductor device DEV1 and the semiconductor device DEV3, since the plurality of slits SLT are formed in the gate electrode GE1, the area ratio of the gate electrode GE1 is reduced.

However, in the semiconductor device DEV3, the upper surface F1 is exposed from the slit SLT, and if a silicide layer is formed on the exposed portion, a short circuit occurs between the gate electrode GE1 and the semiconductor substrate SUB. Therefore, in the semiconductor device DEV3, it is necessary to form a silicide blocking film on the upper surface F1 to cover the exposed portion. By forming the silicide blocking film, the gate electrode GE1 is also covered with the silicide blocking film, preventing the formation of a silicide layer on the gate electrode GE1, which increases the electrical resistance of the gate electrode GE1. On the other hand, in the semiconductor device DEV1, since the slit SLT is formed in the second portion GE1b, that is, the gate electrode GE1 is open only on the drain insulating film DRIF1, the upper surface F1 is not exposed from the slit SLT, and there is no need to form a silicide blocking film. Thus, according to the semiconductor device DEV1, it is possible to reduce the area ratio of the gate electrode GE1 while suppressing the increase in the electrical resistance of the gate electrode GE1.

In the semiconductor device DEV3, slits extending from the end DRIF1a to the end DRIF1b are formed in the drain insulating film DRIF1, whereas in the semiconductor device DEV1, the end DRIF1a is linear in plan view, resulting in fewer corners at the bottom of the drain insulating film DRIF1 compared to the semiconductor device DEV3. Therefore, according to the semiconductor device DEV1, it is possible to suppress HCl (Hot Carrier Injection) degradation caused by the concentration of the electric field at the corners at the bottom of the drain insulating film DRIF1. Furthermore, in the semiconductor device DEV3, since slits are formed in the drain insulating film DRIF1, the dimensional margin when forming the drain insulating film DRIF1 is small. On the other hand, in the semiconductor device DEV1, since no slits are formed in the drain insulating film DRIF1, and the drift layer DRI1 is easily depleted, the dimensional margin when forming the drain insulating film DRIF1 is large.

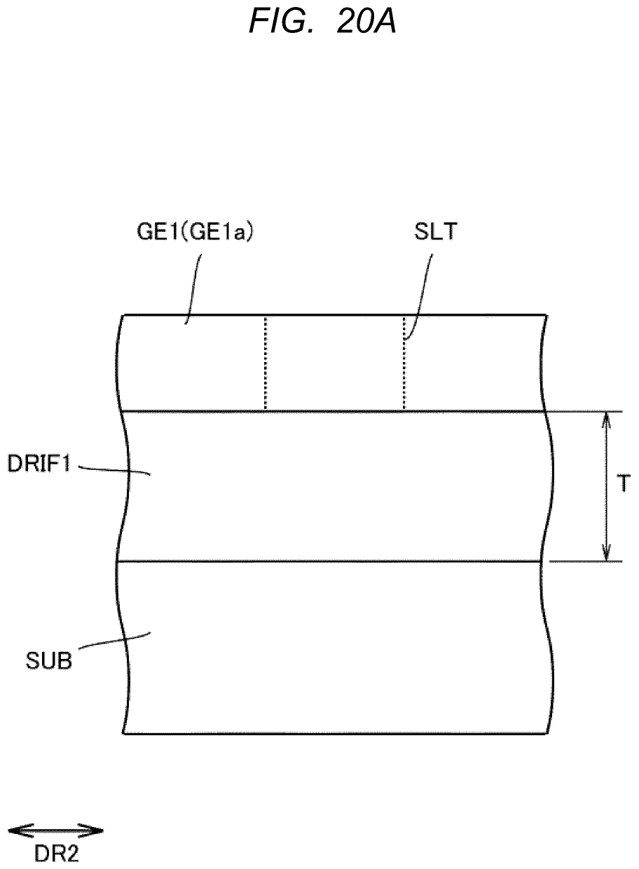

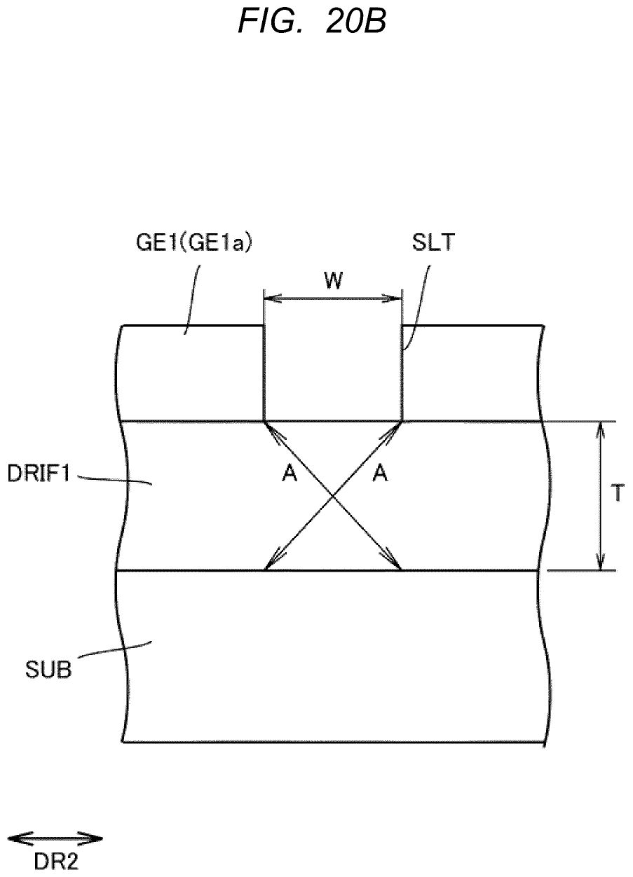

As shown in FIG. 20A, when no slit SLT is formed, the capacitance between the gate electrode GE1 and the semiconductor substrate SUB at the position where the slit SLT is formed becomes Cref. As shown in FIG. 20B, when the slit SLT is formed, as a flange component, the capacitance between the gate electrode GE1 and the semiconductor substrate SUB located on one side of the slit SLT in the short direction (in the example of FIGS. 1, 4, and 5, the second direction DR2, in the example of FIG. 6, the first direction DR1) becomes C1. Also, as a flange component, the capacitance between the gate electrode GE1 and the semiconductor substrate SUB located on the other side of the slit SLT in the short direction becomes C2. When the width of the slit SLT in the short direction is W, and the thickness of the drain insulating film DRIF1 is T, using the value of A in FIG. 20B, Cref, C1, and C2 can be expressed as Cref=k×T, C1=C2=k×A. If A≤2T, then C1+C2×≥Cref, and from the Pythagorean theorem, W≤√3T, that is, if the width of the slit SLT in the short direction is less than or equal to √3 times the thickness of the drain insulating film DRIF1, The first LDMOS transistor of the semiconductor device DEV1 can ensure the same breakdown voltage as when no slit SLT is formed.

When the slit SLT is aligned with the back gate layer BG1 in the first direction DR1 in plan view, that is, when the slit SLT is not aligned with the source layer SL1 in the first direction DR1 in plan view, the drift layer DRI1, which becomes the main current path between the source layer SL1 and the drain layer DRA1, does not face the slit SLT but faces the gate electrode GE1. Therefore, when the first LDMOS transistor is turned on, that is, when a voltage is applied to the gate electrode GE1, an accumulation layer is formed in the drift layer DRI1, which becomes the main current path between the source layer SL1 and the drain layer DRA1. Therefore, in this case, the on-resistance of the first LDMOS transistor can be reduced.

### Second Embodiment

The semiconductor device DEV2 according to the second embodiment will be described. Here, the differences from the semiconductor device DEV1 will be mainly described, and repetitive descriptions will not be repeated.

### Configuration of Semiconductor Device DEV2

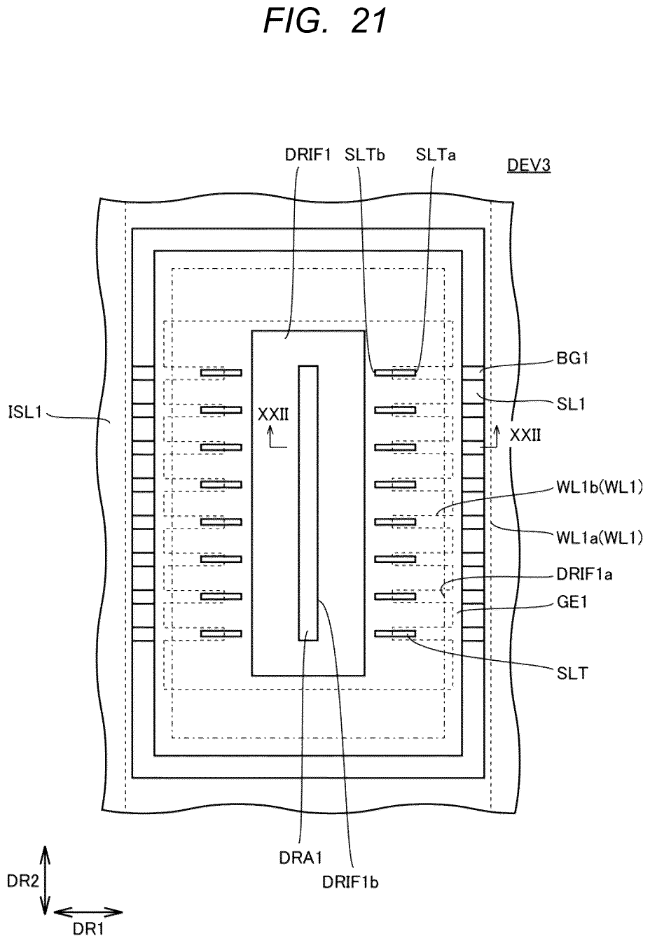

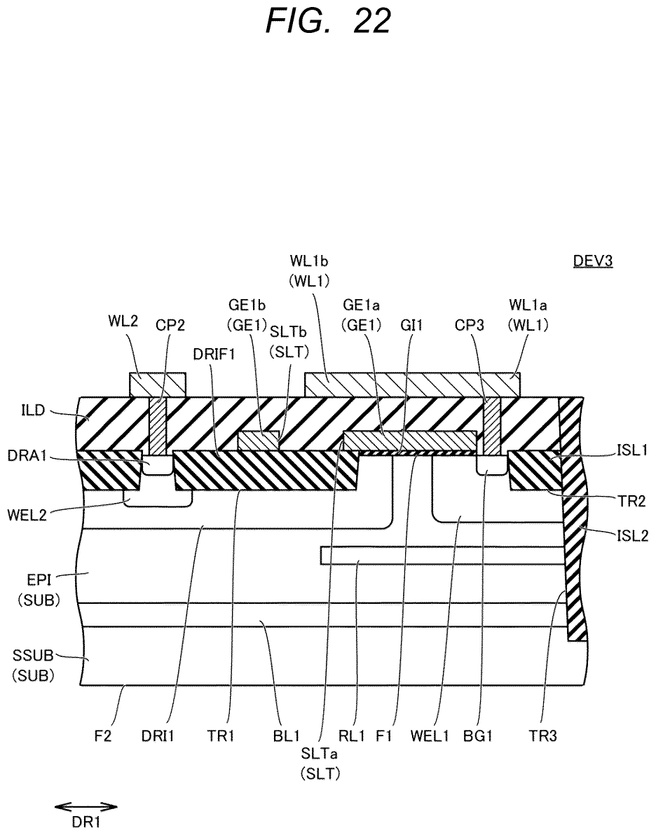

As shown in FIGS. 21 and 22, in the semiconductor device DEV2, the wiring WL1 includes a wiring portion WL1a and a plurality of field plate portion WL1b. The wiring portion WL1a is electrically connected to the source layer SL1 via the contact plug CP1 and is electrically connected to the back gate layer BG1 via the contact plug CP3. The plurality of field plate portions WL1b are connected to the wiring portion WL1a and extend in the first direction DR1 from the wiring portion WL1a. The plurality of field plate portions WL1b are arranged with intervals in the second direction DR2.

Each of the plurality of field plate portions WL1b, in plan view, at least partially overlaps the slit SLT. The tip of the field plate portion WL1b is located between the end SLTa and the end SLTb in the first direction DR1. That is, the field plate portion WL1b, in plan view, overlaps the end of the slit SLT located at least at the end SLTa.

### Modified Example

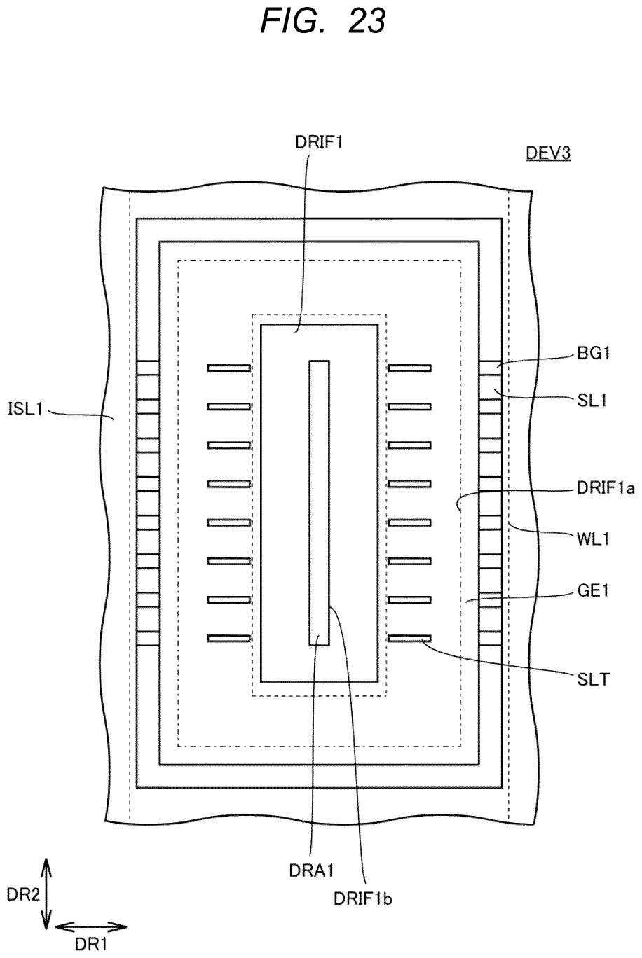

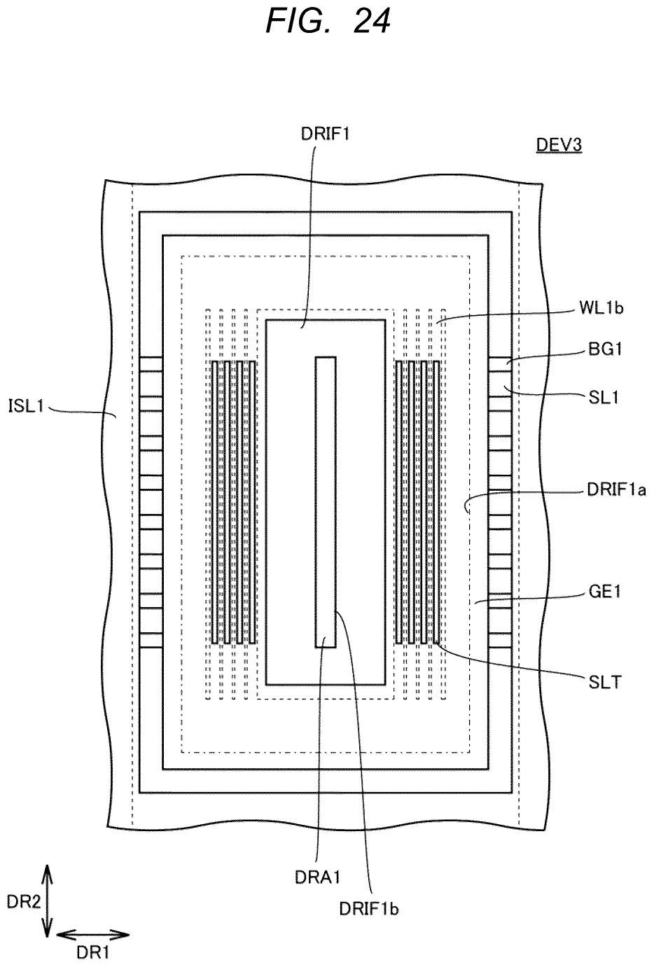

As shown in FIG. 23, the slit SLT may completely overlap the wiring WL1 in plan view. As shown in FIG. 24, when the slit SLT extends in the second direction DR2 and the plurality of slits SLT are spaced apart in the first direction DR1, the field plate portion WL1b extends in the second direction DR2.

### Effect of Semiconductor Device DEV2

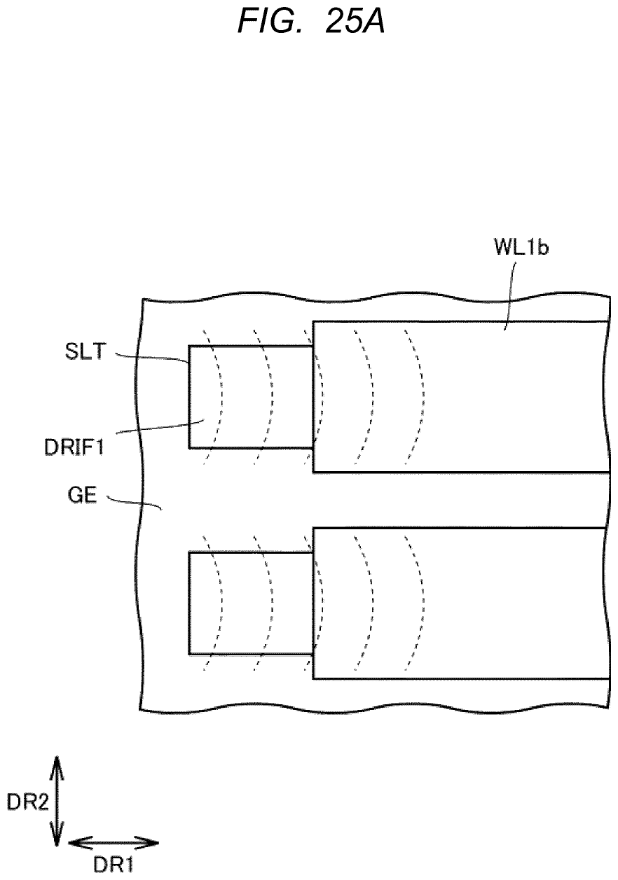

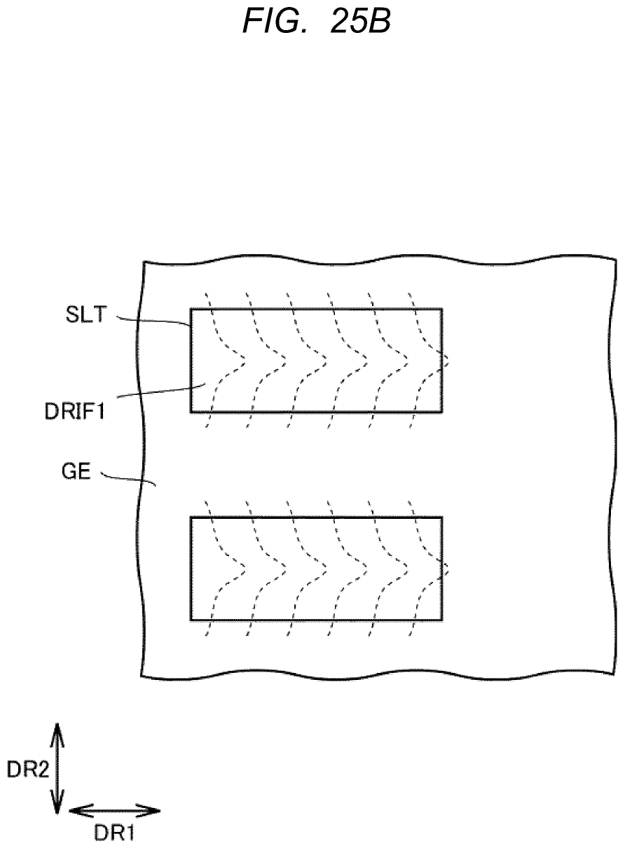

In FIGS. 25A and 25B, the equipment lines are indicated by dotted lines. As shown in FIGS. 25A and 25B, when the wiring WL1 has the field plate portion WL1b, compared to when the wiring WL1 does not have the field plate portion WL1b, the field plate effect due to the wiring WL1 acts in addition to the field plate effect due to the gate electrode GE1, thereby further relaxing the electric field applied to the drift layer DRI1. Therefore, according to the semiconductor device DEV2, the breakdown voltage of the first LDMOS transistor of the semiconductor device DEV2 is further improved. Even if the wiring WL1 only partially overlaps the slit SLT in plan view, as long as the field plate portion WL1b is located at the end SLTa and overlaps the end of the slit SLT where a high electric field is applied, the breakdown voltage of the semiconductor device DEV2 can be sufficiently improved.

Although the invention made by the inventor has been specifically described based on the embodiment, it is needless to say that the present invention is not limited to the above embodiment and various modifications can be made without departing from the gist thereof.

What is claimed is:

1. A semiconductor device comprising:
a semiconductor substrate having an upper surface;
a first source layer formed in the semiconductor substrate and disposed at the upper surface;
a first drain layer formed in the semiconductor substrate and disposed at the upper surface so as to be spaced apart from the first source layer in a first direction;
a first drain insulating film formed at the upper surface and located between the first source layer and the first drain layer in the first direction;
a first gate insulating film formed on the upper surface and located between the first drain insulating film and the first source layer in the first direction; and
a first gate electrode formed on the first gate insulating film and on the first drain insulating film,
wherein the first drain insulating film comprises a first end facing the first source layer and a second end facing the first drain layer in the first direction,
wherein at least one slit is formed in the first gate electrode, the at least one slit penetrates through through the first gate electrode, the at least one slit overlaps the first drain insulating film in plan view while not overlapping the first gate insulating film,
wherein the slit comprises a third end and a fourth end, the fourth end is located on the opposite side of the third end and spaced apart from the first source layer than the third end in the first direction, and
wherein the third end is located between the second end and a boundary between the first drain insulating film and the first gate electrode in the first direction.

2. The semiconductor device according to claim 1,
wherein the at least one slit extends in the first direction.

3. The semiconductor device according to claim 2,
wherein the first gate electrode comprises a fifth end and a sixth end, the six end is located on the opposite side of the fifth end and spaced apart from the first source layer than the fifth end in the first direction, and
wherein the at least one slit extends in the first direction such that the fourth end reaches the sixth end.

4. The semiconductor device according to claim 2,
wherein the at least one slit comprises a plurality of slits,
wherein the plurality of slits are formed in the first gate electrode, and
wherein the plurality of slits are arranged with an interval between two slits of the plurality of slits adjacent to each other so as to form a row in a second direction perpendicular to the first direction in plan view.

5. The semiconductor device according to claim 2,
wherein the at least one slit comprises a plurality of slits,
wherein the plurality of slits are formed in the first gate electrode,
wherein the plurality of slits are arranged with an interval between two slits of the plurality of slits adjacent to each other so as to form a plurality of rows in a second direction perpendicular to the first direction in plan view, and
wherein the plurality of rows are arranged with an interval in the second direction.

6. The semiconductor device according to claim 2,
wherein the semiconductor substrate comprises a first back gate layer formed in the semiconductor substrate and disposed at the upper surface so as to be adjacent to the first source layer in a second direction perpendicular to the first direction in plan view, and
wherein the at least one slit is aligned with the first back gate layer in the first direction.

7. The semiconductor device according to claim 2,
wherein a width of the at least one slit in a second direction perpendicular to the first direction in plan view is less than or equal to √3 times a thickness of the first drain insulating film.

8. The semiconductor device according to claim 1,
wherein the at least one slit extends in a second direction perpendicular to the first direction in plan view.

9. The semiconductor device according to claim 8,
wherein the at least one slit comprises a plurality of slits,
wherein the plurality of slits are formed in the first gate electrode, and
wherein the plurality of slits are arranged with an interval between two slits of the plurality of slits adjacent to each other in the second direction.

10. The semiconductor device according to claim 8,
wherein the width of the at least one slit in the first direction is less than or equal to √3 times a thickness of the first drain insulating film.

11. The semiconductor device according to claim 1, further comprising:
an interlayer insulating film covering the first gate electrode; and
a wiring formed on the interlayer insulating film and electrically connected to the first source layer,
wherein the wiring at least partially overlaps the at least one slit in plan view.

12. The semiconductor device according to claim 11,
wherein the wiring comprises:
a wiring portion extending in a second direction perpendicular to the first direction in plan view so as to overlap the first source layer in plan view; and
a field plate portion extending away from the wiring portion in the first direction so as to partially overlap the at least one slit in plan view, and
wherein a tip of the field plate portion is located between the third end and the fourth end.

13. The semiconductor device according to claim 1, further comprising:
a second source layer formed in the semiconductor substrate and disposed at the upper surface;
a second drain layer formed in the semiconductor substrate and disposed at the upper surface so as to be spaced apart from the second source layer in a third direction;
a second drain insulating film formed at the upper surface and located between the second source layer and the second drain layer in the third direction;
a second gate insulating film formed on the upper surface and located between the second drain insulating film and the second source layer in the third direction; and
a second gate electrode formed on the second gate insulating film and on the second drain insulating film,
wherein the second gate electrode is formed such that no slit is formed in the second gate electrode.
